(19) United States
(12) Patent Application Publication
(10) Pub. No.: US 2016/0115622 A1
(43) Pub. Date: Apr. 28, 2016

(54) VAPOR PHASE GROWTH APPARATUS AND VAPOR PHASE GROWTH METHOD

(71) Applicant: NuFlare Technology, Inc., Kanagawa (JP)

(72) Inventors: Hideki ITO, Yokohama (JP); Yuusuke SATO, Tokyo (JP)

(21) Appl. No.: 14/921,159

(22) Filed: Oct. 23, 2015

(30) Foreign Application Priority Data
Oct. 27, 2014 (JP) 2014-218657

(51) Int. Cl. C30B 25/02; C30B 25/12

(52) U.S. Cl. CPC C30B 25/02; C30B 25/12

(57) ABSTRACT

A vapor phase growth apparatus according to an embodiment includes n (n is an integer equal to or greater than 1) reaction chambers each processing a substrate under a pressure less than atmospheric pressure, a cassette chamber having a cassette holding portion capable of placing a cassette holding the substrate on the cassette holding portion, internal pressure of the cassette chamber being able to be reduced to a pressure less than the atmospheric pressure, a transferring chamber provided between the reaction chamber and the cassette chamber and transferring the substrate under a pressure less than the atmospheric pressure, and a substrate standby portion capable of simultaneously holding n or more substrates processed in the reaction chamber and provided in a region having a heat-resistant temperature of 500° C. or more, internal pressure of the region being able to be reduced to a pressure less than the atmospheric pressure.

### CROSS-REFERENCE TO RELATED APPLICATION

This application is based upon and claims the benefit of priority from Japanese Patent Applications No. 2014-218657, filed on Oct. 27, 2014, the entire contents of which are incorporated herein by reference.

### FIELD OF THE INVENTION

The invention relates to a vapor phase growth apparatus and a vapor phase growth method that supply gas to form a film.

### BACKGROUND OF THE INVENTION

As a method for forming a high-quality semiconductor film, there is an epitaxial growth technique which grows a single-crystal film on a substrate, such as a wafer, using vapor phase growth. In a vapor phase growth apparatus using the epitaxial growth technique, a wafer is placed on a support portion in a reaction chamber which is maintained at normal pressure or reduced pressure. Then, process gas, such as source was which will be a raw material for forming a film, is supplied from an upper part of the reaction chamber to the surface of the wafer while the wafer is being heated. For example, the thermal reaction of the source gas occurs in the surface of the wafer and an epitaxial single-crystal film is formed on the surface of the wafer.

It is necessary to improve productivity in the formation of the epitaxial single-crystal film. JPH11-29392 discloses an epitaxial growth apparatus including a cooling chamber which cools a substrate processed in a reaction chamber in order to improve productivity.

### SUMMARY OF THE INVENTION

A vapor phase growth apparatus according to an embodiment of the invention includes: n (n is an integer equal to or greater than 1) reaction chambers each processing a substrate under a pressure less than atmospheric pressure; a cassette chamber having a cassette holding portion capable of placing a cassette holding the substrate on the cassette holding portion, internal pressure of the cassette chamber being able to be reduced to a pressure less than the atmospheric pressure; a transferring chamber which is provided between the reaction chamber and the cassette chamber and transfers the substrate under a pressure less than the atmospheric pressure; and a substrate standby portion that is capable of simultaneously holding n or more substrates processed in the reaction chamber and is provided in a region having a heat-resistant temperature of 500° C. or more, internal pressure of the region being able to be reduced to a pressure less than the atmospheric pressure.

A vapor phase growth method according to another embodiment of the invention includes: placing a cassette holding a plurality of substrates on a cassette holding portion provided in a cassette chamber; reducing the internal pressure of the cassette chamber to a pressure less than atmospheric pressure; transferring the substrate from the cassette chamber to a transferring chamber with an internal pressure less than the atmospheric pressure; transferring the substrate from the transferring chamber to a reaction chamber selected from n (n is an integer equal to or greater than 1) reaction chambers having an internal pressure adjusted to a pressure less than the atmospheric pressure; heating the substrate at a temperature of 500° C. or more in the selected reaction chamber and supplying a process gas to the selected reaction chamber to form a film on the substrate; transferring the substrate from the selected reaction chamber to the transferring chamber having an internal pressure less than the atmospheric pressure; transferring the substrate from the transferring chamber to a substrate standby portion having an internal pressure less than the atmospheric pressure and a heat-resistant temperature of 500° C. or more and unload. (taking out) the substrate from the substrate standby portion and inserting the substrate into the cassette after the temperature of the substrate is reduced to less than 100° C.

### BRIEF DESCRIPTION OF THE DRAWINGS

FIG. 1 is a plan view schematically illustrating a vapor phase growth apparatus according to a first embodiment;

FIG. 2 is a cross-sectional view schematically illustrating the vapor phase growth apparatus according to the first embodiment;

FIG. 3 is a plan view schematically illustrating a vapor phase growth apparatus according to a second embodiment; and

FIG. 4 is a plan view schematically illustrating a vapor phase growth apparatus according to a third embodiment.

### DETAILED DESCRIPTION OF THE EMBODIMENTS

Hereinafter, embodiments of the invention will be described with reference to the drawings.

In the specification, the direction of gravity in a state in which a vapor phase growth apparatus is provided so as to form a film is defined as a “lower” direction and a direction opposite to the direction of gravity is defined as an “upper” direction. Therefore, a “lower portion” means the position of the direction of gravity relative to the reference and a “lower side” means the direction of gravity relative to the reference. In addition, an “upper portion” means a position in the direction opposite to the direction of gravity relative to the reference and an “upper side” means the direction opposite to the direction of gravity relative to the reference. Furthermore, a “longitudinal direction” is the direction of gravity.

In the specification, the term “heat-resistant temperature” means a temperature at which a target material maintains its function, without any deformation and any change in quality, in a state in which no force is applied to the target material. For example, a polypropylene (PP) resin has a heat-resistant temperature of about 100° C. to 140° C. For example, quartz glass has a heat-resistant temperature of about 1000° C. In addition, silicon carbide has a heat-resistant temperature of 1600° C. or more.

In the specification, a “process gas” generally indicates gas which is used to form a film on a substrate. The concept of the “process gas” includes, for example, a source gas, a carrier gas, and a separation gas.

In the specification, the “separation gas” is a process gas which is introduced into a reaction chamber of the vapor phase growth apparatus and generally indicates gas which separates the process gases which are a plurality of raw material gases.

### First Embodiment

A vapor phase growth apparatus according to this embodiment of the invention includes: n (n is an integer equal to or greater than 1) reaction chambers each processing a substrate under a pressure less than atmospheric pressure; a cassette chamber which has a cassette holding portion on which a cassette holding the substrate can be placed and whose internal pressure can be reduced to a pressure less than the atmospheric pressure; a transferring chamber which is provided between the reaction chamber and the cassette chamber and transfers the substrate under a pressure less than the atmospheric pressure; and a substrate standby portion that is capable of simultaneously holding n or more substrates processed in the reaction chamber and is provided in a region which has a heat-resistant temperature of 500° C. or more and whose internal pressure can be reduced to a pressure less than the atmospheric pressure.

A vapor phase growth method according to this embodiment of the invention includes: placing a cassette holding a plurality of substrates on a cassette holding portion provided in a cassette chamber; reducing the internal pressure of the cassette chamber to a pressure less than atmospheric pressure; transferring the substrate from the cassette chamber to a transferring chamber with an internal pressure less than the atmospheric pressure; transferring the substrate from the transferring chamber to a reaction chamber selected from n (n is an integer equal to or greater than 1) reaction chambers having an internal pressure adjusted to a pressure less than the atmospheric pressure; heating the substrate at a temperature of 500° C. or more in the selected reaction chamber and supplying a process gas to the selected reaction chamber to form a film on the substrate; transferring the substrate from the selected reaction chamber to the transferring chamber having an internal pressure less than the atmospheric pressure; transferring the substrate from the transferring chamber to a substrate standby portion having an internal pressure less than the atmospheric pressure and a heat-resistant temperature of 500° C. or more; and unloading (taking out) the substrate from the substrate standby portion and inserting the substrate into the cassette after the temperature of the substrate is reduced to less than 100° C.

Since the vapor phase growth apparatus and the vapor phase growth method according to this embodiment have the above-mentioned structures, the substrate standby portion can hold the high-temperature substrate which is unloaded from the high-temperature reaction chamber and has a film formed thereon before the substrate is inserted into the cassette. Therefore, it is possible to continuously form films on the next substrate, regardless of the time required to cool the substrate to a temperature at which the substrate can be inserted into the cassette with low heat resistance. As a result, productivity is improved when films are continuously formed on a plurality of substrates.

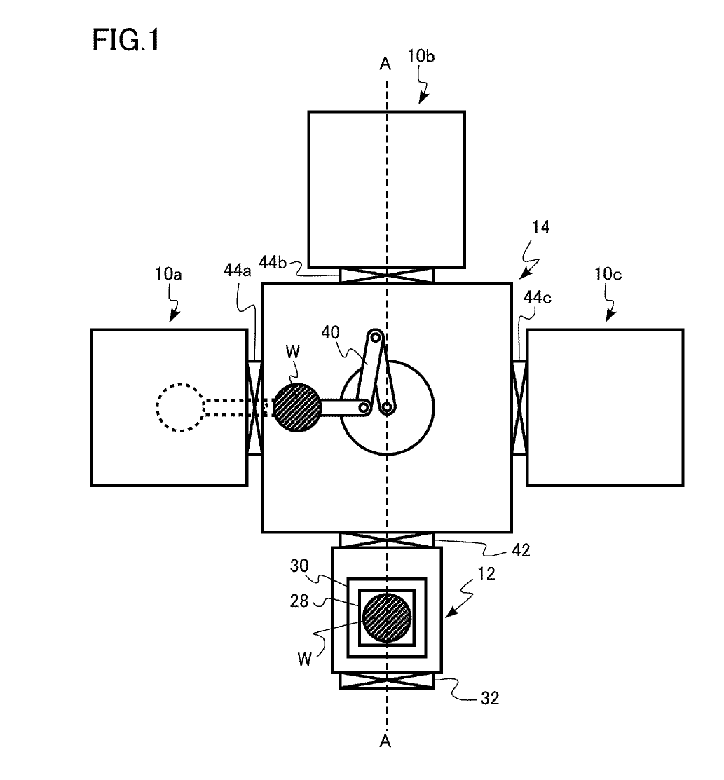

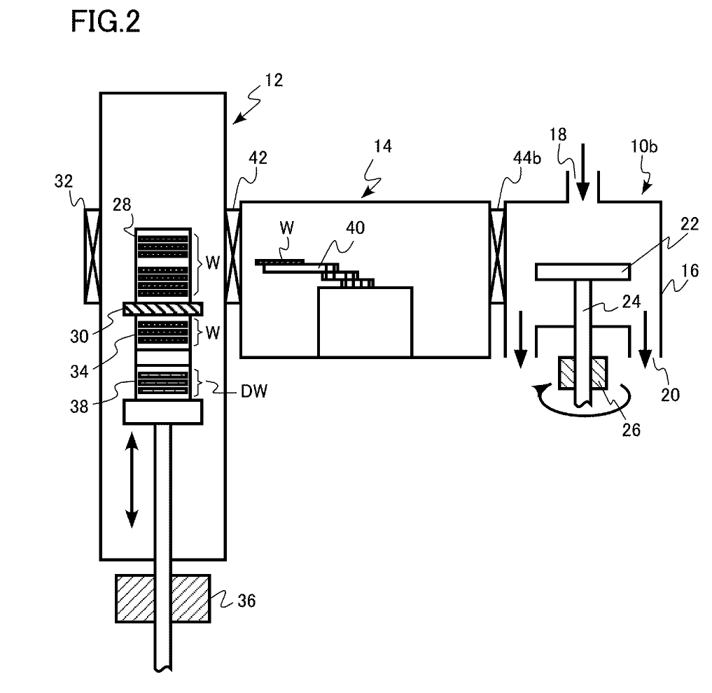

FIG. 1 is a plan view schematically illustrating a vapor phase growth apparatus according to this embodiment. FIG. 2 is a cross-sectional view schematically illustrating the vapor phase growth apparatus according to this embodiment. FIG. 2 illustrates a cross section corresponding to the cross section taken along the line A-A of FIG. 1.

The vapor phase growth apparatus according to this embodiment is a single-wafer-type epitaxial growth apparatus that uses a metal organic chemical vapor deposition (MOCVD) method.

The vapor phase growth apparatus according to this embodiment includes three reaction chambers 10a, 10b, and 10c that process a wafer (substrate) W under a pressure equal to or less than atmospheric pressure. In addition, the vapor phase growth apparatus includes a cassette chamber 12 whose internal pressure can be reduced to a pressure less than atmospheric pressure. The vapor phase growth apparatus further includes a transferring chamber 14 that is provided between the reaction chambers 10a, 10b, and 10c and the cassette chamber 12 and transfers the wafer (substrate) W under a pressure less than atmospheric pressure.

Each of the three reaction chambers 10a, 10b, and 10c is, for example, a vertical single-wafer-type epitaxial growth apparatus. The number of reaction chambers is not limited to 3 and one or more reaction chambers may be used. The number of reaction chambers can be represented by n (n is an integer equal to or greater than 1). It is preferable that the number of reaction chambers be equal to or greater than 3 in order to improve productivity.

Each of the reaction chambers 10a to 10c includes, for example, a wall surface 16 of a stainless cylindrical hollow body. A gas supply port 18 for supplying process gas is provided in an upper part of each of the reaction chambers 10a to 10c. In addition, a gas discharge port 20 that discharges a reaction product obtained by the reaction of a source gas on the surface of the wafer Wand a residual process gas in the reaction chambers 10a to 10c to the outside of the reaction chambers 10a to 10c is provided at the bottom of each of the reaction chambers 10a to 10c.

Each reaction chamber includes a support portion 22 which is provided below the gas supply port 18 in the reaction chamber and on which the wafer (substrate) W can be placed. The support portion 22 is, for example, an annular holder that has an opening formed at the center thereof or a susceptor that comes into contact with the substantially entire rear surface of the wafer W.

Each reaction chamber includes a rotating shaft 24 on which the support portion 22 is provided and a rotating mechanism 26 which rotates the rotating shaft 24. In addition, each reaction chamber includes a heater as a heating unit (not illustrated) that heats the wafer W placed on the support portion 22.

The cassette chamber 12 includes a cassette table 30 on which a cassette 28 holding a plurality of wafers W can be placed. The cassette table 30 is an example of a cassette holding portion. The cassette 28 is made of, for example, resin or aluminum having a heat-resistant temperature less than 500° C. The cassette 28 can hold, for example, 25 wafers W.

The cassette chamber 12 is provided with a gate valve 32. The cassette 28 can be loaded from the outside of the apparatus to the cassette chamber 12 through the gate valve 32. The gate valve 32 is closed and a vacuum pump (not illustrated) is operated to reduce the internal pressure of the cassette chamber 12 to a pressure less than atmospheric pressure.

The cassette chamber 12 includes a substrate standby portion 34. When the number of reaction chambers is n, the substrate standby portion 34 can simultaneously hold n or more substrates processed by the reaction chambers. The substrate standby portion 34 has a heat-resistant temperature of 500° C. or more. The substrate standby portion 34 is made of a material having a higher heat-resistant temperature than that forming the cassette 28.

The substrate standby portion 34 is made of, for example, quartz glass. In addition, the substrate standby portion 34 is made of ceramics such as silicon carbide. Furthermore, the substrate standby portion 34 is made of a metal material such as SUS.

The substrate standby portion 34 is provided in a region whose internal pressure can be reduced to a pressure less than atmospheric pressure. In this embodiment, the substrate standby portion 34 is provided in the cassette chamber 12 whose internal pressure can be reduced to a pressure less than atmospheric pressure.

In this embodiment, the cassette table 30 and the substrate standby portion 34 are arranged in a line in the direction of gravity. That is, the cassette table 30 and the substrate standby portion 34 are vertically arranged. The vapor phase growth apparatus according to this embodiment includes a lifting mechanism (lift) 36 that moves up and down the cassette table 30 and the substrate standby portion 34.

In this embodiment, the cassette chamber 12 further includes a dummy substrate storage portion 38 which can simultaneously hold n or more dummy wafers (dummy substrates) DW different from the wafers W stored in the cassette 28 or the substrate standby portion 34 when the number of reaction chambers is n.

For example, the dummy wafer DW is placed on the support portion 22 when a cleaning process is performed for the reaction chambers 10a to 10c and has a function of protecting the support portion 22 or the heater. The dummy wafer DW is, for example, a silicon carbide (SIC) wafer.

The dummy substrate storage portion 38 has a heat-resistant temperature of 500° C. or more. The dummy substrate storage portion 38 is made of a material having a higher heat-resistant temperature than that forming the cassette table 30.

The dummy substrate storage portion 38 is made of, for example, quartz glass. In addition, the dummy substrate storage portion 38 is made of ceramics such as silicon carbide. Furthermore, the dummy substrate storage portion 38 is made of a metal material such as SUS.

The dummy substrate storage portion 38 is provided in a region whose internal pressure can be reduced to a pressure less than atmospheric pressure. In this embodiment, the dummy substrate storage portion 38 is provided in the cassette chamber 12 whose internal pressure can be reduced to a pressure less than atmospheric pressure.

In this embodiment, the cassette table 30, the substrate standby portion 34, and the dummy substrate storage portion 38 are arranged in a line in the direction of gravity. That is, the cassette table 30, the substrate standby portion 34, and the dummy substrate storage portion 38 are vertically arranged. In addition, the dummy substrate storage portion 38 can be moved up and down together with the cassette table 30 and the substrate standby portion 34 by the lifting mechanism 36.

The transferring chamber 14 includes a robot arm 40 for moving the wafer W between the cassette chamber 12 and the reaction chambers 10a to 10c. A gate valve 42 is provided between the cassette chamber 12 and the transferring chamber 14. In addition, gate valves 44a, 44b, and 44c are provided between the reaction chambers 10a to 10c and the transferring chamber 14.

The robot arm 40 can move the wafer W between the cassette chamber 12 and the transferring chamber 14 through the gate valve 42. In addition, the robot arm 40 can move the wafer W between the transferring chamber 14 and the reaction chambers 10a, 10b, and 10c through the gate valves 44a, 44b, and 44c.

Next, a vapor phase growth method according to this embodiment will be described. The vapor phase growth method according to this embodiment uses the epitaxial growth apparatus illustrated in FIGS. 1 and 2. Hereinafter, an example in which a gallium nitride (GaN) film is epitaxially grown on the wafer N be described.

First, a plurality of wafers (substrates) N, for exam 24 wafers N are stored in the cassette 28 which is made of a resin having a heat-resistant temperature less than 500° C. in the atmosphere outside the apparatus. The wafer N is, for example, a silicon (Si) wafer. Then, the gate valve 32 is opened and the cassette 28 is placed on the cassette table 30 provided in the cassette chamber 12.

A plurality of dummy wafers (dummy substrates) DW, for example, three dummy wafers DW are stored in the dummy substrate storage portion 38. It is assumed that the number of dummy wafers DW is equal to or greater than the number of reaction chambers.

Then, the gate valve 32 is closed and a vacuum pump (not illustrated) is operated to reduce the internal pressure of the cassette chamber 12 to a pressure less than atmospheric pressure. Then, the gate valve 42 is opened and a first wafer (substrate to be processed), which is one of a plurality of wafers W, is transferred from the cassette chamber 12 to the transferring chamber 14.

At that time, the lifting mechanism 36 is used to adjust the position of the cassette 28 in the vertical direction to a height where the first wafer is taken out by the robot arm 40. The internal pressure of the transferring chamber 14 is reduced to a pressure less than atmospheric pressure by a vacuum pump (not illustrated) in advance.

Then, the gate valve 44a is opened and the first wafer is loaded to the reaction chamber 10a by the robot arm 40 and is then placed on the support portion 22. This process is repeatedly performed to load a second wafer, which is one of the plurality of wafers stored in the cassette 28, to the reaction chamber 10b and to place the second wafer on the support portion 22. In addition, a third wafer, which is one of the plurality of wafers stored in the cassette 28, is loaded to the reaction chamber 10c and is then placed on the support portion 22.

After the first, second, and third wafers are loaded to the reaction chambers 10a, 10b, and 10c, respectively, the gate valves 44a, 44b, and 44c are closed. The internal pressure of the reaction chambers 10a to 10c is reduced to a pressure less than atmospheric pressure by a vacuum pump (not illustrated) in advance.

Then, the rotating mechanism 26 rotates the support portion 22 and the heater heats the first, second, and third wafers. The first, second, and third wafers are heated temperature of 500° C. or more, for example, 1000° C.

Then, trimethylgallium (TMG) of organic metal having hydrogen gas as a main carrier gas and ammonia are supplied from the gas supply ports 18 of the reaction chambers 10a to 10c. In this way, the GaN film is epitaxially grown on the surfaces of the first, second, and third wafers at the same time.

After the epitaxial growth is completed, the gate valve 44a is opened and the first wafer is unloaded from the reaction chamber 10a to the transferring chamber 14 by the robot arm 40. In addition, the first wafer is transferred from the transferring chamber 14 to the substrate standby portion 34 which has a pressure less than atmospheric pressure and a heat-resistant temperature of 500° C. or more and is then stored in the substrate standby portion 34. At that time, the lifting mechanism 36 is used to adjust the position of the substrate standby portion 34 in the vertical direction to a height where the first wafer can be stored at a desired position by the robot arm 40. At that time, the first wafer is in a high-temperature state of, for example, 500° C. or more.

Similarly, the second and third wafers are transferred and stored in the substrate standby portion 34. At that time, the second and third wafers are in a high-temperature state of, for example, 500° C. or more.

Then, for example, a first dummy wafer which is one of the plurality of dummy wafers DW is transferred from the dummy substrate storage portion 38 of the cassette chamber 12 to the transferring chamber 14. At that time, the lifting mechanism 36 is used to adjust the position of the dummy substrate storage portion 38 in the vertical direction to a height where the first dummy wafer is taken out by the robot arm 40.

Then, the first dummy wafer is loaded to the reaction chamber 10a by the robot arm 40 and is then placed on the support portion 22. This process is repeatedly performed to load a second dummy wafer, which is one of the plurality of dummy wafers DW stored in the dummy substrate storage portion 38, to the reaction chamber 10b and to place the second dummy wafer on the support portion 22. In addition, a third dummy wafer, which is one of the plurality of dummy wafers DW stored in the dummy substrate storage portion 38, is loaded to the reaction chamber 10c and is then placed on the support portion 22.

Then, the rotating mechanism 26 rotates the support portion 22 and the heater heats the first, second, and third dummy wafers. Then, a chlorine-based gas, for example, a hydrogen chloride (HCl) gas is supplied from the gas supply port 18 of each of the reaction chambers 10a to 10c. In this way, cleaning is simultaneously performed in the reaction chambers 10a to 10c. The first, second, and third dummy wafers prevent, for example, the support portion 22 or the heater from deteriorating due to the chlorine-based gas.

After the cleaning process is completed, the gate valve 44a is opened and the first dummy wafer is unloaded from the reaction chamber 10a to the transferring chamber 14 by the robot arm 40. In addition, the first dummy wafer is transferred from the transferring chamber 14 to the dummy substrate storage portion 38 and is then stored in the dummy substrate storage portion 38 which has a heat-resistant temperature of 500° C. or more under a pressure less than atmospheric pressure. At that time, the lifting mechanism 36 is used to adjust the position of the dummy substrate storage portion 38 in the vertical direction to a height where the first dummy wafer can be stored by the robot arm 40. At that time, the first dummy wafer is in a high-temperature state of, for example, 500° C. or more.

Similarly, the second and third dummy wafers are transferred and stored in the dummy substrate storage portion 38. At that time, the second and third dummy wafers are in a high-temperature state of, for example, 500° C. or more.

Then, similarly to the first, second, and third wafers, GaN films are epitaxially grown on fourth, fifth, and sixth wafers among the plurality of wafers W stored in the cassette 28 at the same time. Then, cleaning is simultaneously performed in the reaction chambers 10a to 10c, using the first, second, and third dummy wafers.

After the temperature of the first, second, and third wafers (substrates to be processed) stored in the substrate standby portion 34 is reduced to be less than 100° C., the robot arm 40 is used to take out the first, second, and third wafers from the substrate standby portion 34 and to insert them into the cassette 28. For example, while GaN films are being formed on the fourth, fifth, and sixth wafers or while the reaction chambers 10a to 10c are being cleaned, the first, second, and third wafers are moved from the substrate standby portion 34 to the cassette 28. After the temperature of the first, second, and third wafers is reduced to less than the heat-resistant temperature of the cassette 28, the first, second, and third wafers are moved.

This process is repeatedly performed to grow the GaN films on all of 24 wafers W stored in the cassette 28. After all of 24 wafers W are stored in the cassette 28, the gate valve 42 is closed and the internal pressure of the cassette chamber increases to normal pressure. Then, the gate valve 32 is opened and the cassette 28 is unloaded to the outside of the apparatus.

Next, the function and effect of this embodiment will be described.

In this embodiment, the internal pressure of the cassette chamber 12 can be reduced to a pressure less than atmospheric pressure. Therefore, the cassette chamber 12 and the transferring chamber 14 can be maintained at the same reduced pressure. When films are continuously formed on a plurality of wafers W stored in the cassette 28, it is not necessary to adjust the pressure of the cassette chamber 12 and the transferring chamber 14 every time the wafer W is moved between the cassette chamber 12 and the transferring chamber 14. Therefore, it is possible to reduce the time required to adjust pressure and to improve productivity.

It is preferable that a resin cassette (carrier) 28 which is generally used to insert wafers into a carrier box in a production line be used as the cassette 28 placed on the cassette table 30 in order to improve productivity. The resin cassette 28 generally has a low heat-resistant temperature less than 500° C.

Therefore, when the resin cassette 28 is used, it is difficult to insert the high-temperature wafer W into the cassette 28 immediately after the formation of films is completed. Therefore, the wafer W on which the formation of films has been completed needs to wait in the reaction chambers 10a to 10c or the transferring chamber 14 until the temperature of the wafer W is reduced to a value at which the wafer W can be stored in the cassette 28, which results in a reduction in productivity.

In the vapor phase growth apparatus according to this embodiment, the cassette chamber 12 includes the substrate standby portion 34 having a heat-resistant temperature of 500° C. or more. Therefore, for example, even when the cassette 28 having a heat-resistant temperature less than 500° C. is used, the wafer W on which the formation of films has been completed and which has a high temperature of 500° C. or more can be stored in the substrate standby portion 34.

Therefore, the time required to wait for a reduction in the temperature of the wafer W does not prevent the formation of films on the next wafer. As a result, productivity is improved.

In addition, in the vapor phase growth apparatus according to this embodiment, the cassette chamber 12 includes the dummy substrate storage portion 38 having a heat-resistant temperature of 500° C. or more. Therefore, similarly to the case in which films are formed on the wafer W, when the reaction chambers 10a to 10c are cleaned, it is possible to reduce the time required to adjust pressure during the movement of the dummy wafer between the cassette chamber 12 and the transferring chamber 14. In addition, the time required to wait for a reduction in the temperature of the dummy wafer DW does not prevent the formation of films on the next wafer or cleaning. As a result, productivity is improved.

In this embodiment, the cassette table 30, the substrate standby portion 34 and the dummy substrate storage portion 38 are arranged in a line in the direction of gravity in the cassette chamber 12. Therefore, even though the substrate standby portion 34 and the dummy substrate storage portion 38 are provided, the plane area of the cassette chamber 12 does not increase. In other words, it is possible to reduce a so-called footprint of the vapor phase growth apparatus. In addition, for example, the operation distance and operation time of the robot arm 40 are reduced, as compared to a case in which the cassette table 30 and the substrate standby portion 34 are separated from each other in a plan view. Therefore, productivity is improved from this point of view.

As described above, according to this embodiment, it is possible to achieve a vapor phase growth apparatus and a vapor phase growth method in which the time required to wait for a reduction in the temperature of the substrate after a high-temperature process does not prevent a reduction in productivity and productivity is improved.

### Second Embodiment

A vapor phase growth apparatus according to this embodiment is similar to the vapor phase growth apparatus according to the first embodiment except that the substrate standby portion and the dummy substrate storage portion are not provided in the cassette chamber, but are provided in the transferring chamber. Therefore, the description of the same structures as those in the first embodiment will not be repeated.

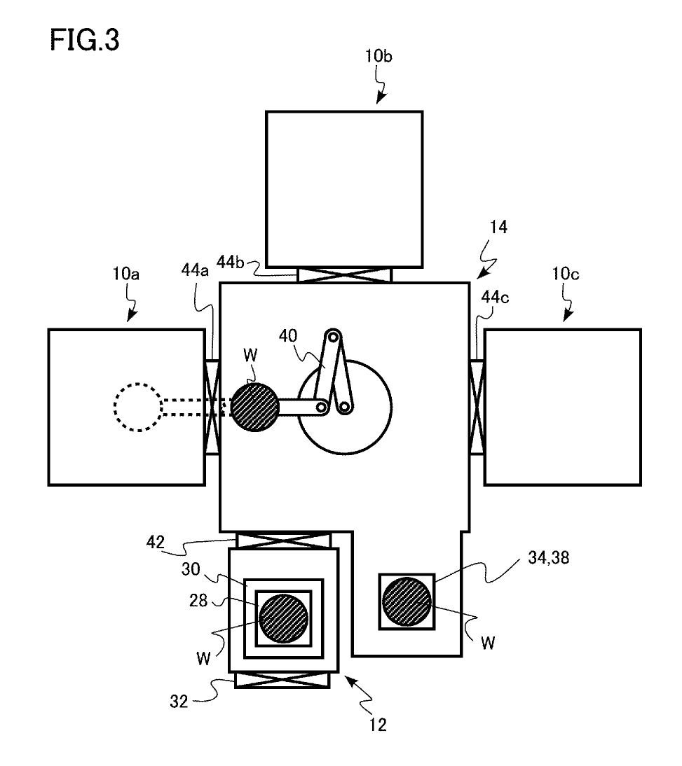

FIG. 3 is a plan view schematically illustrating the vapor phase growth apparatus according to this embodiment. In the vapor phase growth apparatus according to this embodiment, a substrate standby portion 34 and a dummy substrate storage portion 38 are provided in a transferring chamber 14 whose internal pressure can be reduced to a pressure less than atmospheric pressure.

According to this embodiment, similarly to the first embodiment, it is possible to achieve a vapor phase growth apparatus and a vapor phase growth method which improve productivity.

### Third Embodiment

A vapor phase growth apparatus according to this embodiment differs from the vapor phase growth apparatus according to the first embodiment in the arrangement of the cassette chamber, the transferring chamber, and the reaction chamber. Therefore, the description of the same structures as those in the first embodiment will not be repeated.

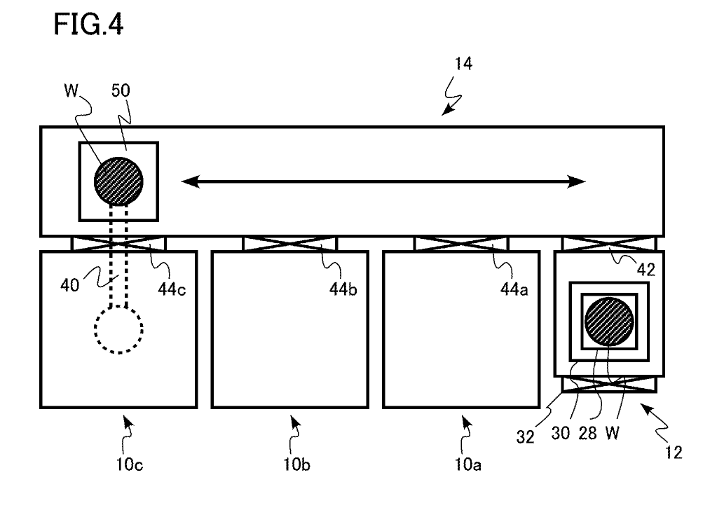

FIG. 4 is a plan view schematically illustrating the vapor phase growth apparatus according to this embodiment. In the vapor phase growth apparatus according to this embodiment, a transferring stand 50, which is provided with a robot arm 40 and can be linearly moved, is provided in the transferring chamber 14. Reaction chambers 10a, 10b, and 10c and a cassette chamber 12 are provided on the same side surface of the transferring chamber 14. The reaction chambers 10a, 10b, and 10c and the cassette chamber 12 have the same internal structures as those in the first embodiment.

In this embodiment, the transferring stand 50 is moved to move a wafer W or a dummy wafer DW between the reaction chambers 10a to 10c and the cassette chamber 12.

According to this embodiment, similarly to the first embodiment, it is possible to achieve a vapor phase growth apparatus and a vapor phase growth method which improve productivity.

The embodiments of the invention have been described above with reference to examples. The above-described embodiments are illustrative examples and do not limit the invention. In addition, the components according to each embodiment may be appropriately combined with each other.

For example, in the above-described embodiments, the GaN (gallium nitride) single-crystal film is formed. However, for example, the invention can be applied to form other group III-V nitride-based semiconductor single-crystal films, such as AlN (aluminum nitride), AlGaN (aluminum gallium nitride), and InGaN (indium gallium nitride) single-crystal films. In addition, the invention can be applied to a group III-V semiconductor such as GaAs. Furthermore, the invention can be applied to form a semiconductor film, such as a Si (silicon) other than the group III-V semiconductor films.

In the above-described embodiments, organic metal is one kind of TMG. However, two or more kinds of organic metal may be used as the source of a group III element. In addition, organic metal may be an element other than the group III element.

In the above-described embodiments, hydrogen gas (H₂) is used as the carrier gas. However, nitrogen gas (N₂), argon gas (Ar), helium gas (He), or a combination of the gases can be applied as the carrier gas.

In the above-described embodiments, for example, portions which are not necessary to describe the invention, such as the structure of the apparatus or a manufacturing method, are not described. However, the necessary structure of the apparatus or a necessary manufacturing method can be appropriately selected and used. In addition, all of the vapor phase growth apparatuses and the vapor phase growth methods which include the components according to the invention and whose design can be appropriately changed by those skilled in the art are included in the scope of the invention. The scope of the invention is defined by the scope of the claims and the scope of equivalents thereof.

What is claimed is:

1. A vapor phase growth apparatus comprising:
n (n is an integer equal to or greater than 1) reaction chambers each processing a substrate under a pressure less than atmospheric pressure;
a cassette chamber having a cassette holding portion capable of placing a cassette holding the substrate on the cassette holding portion, internal pressure of the cassette chamber being able to be reduced to a pressure less than the atmospheric pressure;
a transferring chamber provided between the reaction chamber and the cassette chamber, the transferring chamber configured to transfer the substrate under a pressure less than the atmospheric pressure; and
a substrate standby portion capable of simultaneously holding n or more substrates processed in the reaction chamber and provided in a region having a heat-resistant temperature of 500° C. or more, internal pressure of the region being able to be reduced to a pressure less than the atmospheric pressure.

2. The vapor phase growth apparatus according to claim 1,
wherein the substrate standby portion is provided in the cassette chamber.

3. The vapor phase growth apparatus according to claim 1, further comprising:
a dummy substrate storage portion capable of simultaneously holding n or more dummy substrates and provided in a region having a heat-resistant temperature of 500° C. or more, internal pressure of the region being able to be reduced to a pressure less than the atmospheric pressure.

4. The vapor phase growth apparatus according to claim 2, further comprising:
a lift moving up and down the cassette holding portion and the substrate standby portion,
wherein the cassette holding portion and the substrate standby portion are arranged in a line in a direction of gravity.

5. The vapor phase growth apparatus according to claim 1,
wherein the substrate standby portion is provided in the transferring chamber.

6. The vapor phase growth apparatus according to claim 1,
wherein the substrate standby portion is made of quartz glass, ceramics, or metal.

7. The vapor phase growth apparatus according to claim 4,
wherein a dummy substrate storage portion is made of quartz glass, ceramics, or metal.

8. A vapor phase growth method comprising:
placing a cassette holding a plurality of substrates on a cassette holding portion provided in a cassette chamber;
reducing the internal pressure of the cassette chamber to a pressure less than atmospheric pressure;
transferring one of the substrates from the cassette chamber to a transferring chamber with an internal pressure less than the atmospheric pressure;
transferring the one of the substrates from the transferring chamber to a reaction chamber selected from n (n is an integer equal to or greater than 1) reaction chambers having an internal pressure adjusted to a pressure less than the atmospheric pressure;
heating the one of the substrates at a temperature of 500° C. or more in the selected reaction chamber and supplying a process gas to the selected reaction chamber to form a film on the substrate;
transferring the one of the substrates from the selected reaction chamber to the transferring chamber having an internal pressure less than the atmospheric pressure;
transferring the one of the substrates from the transferring chamber to a substrate standby portion having an internal pressure less than the atmospheric pressure and a heat-resistant temperature of 500° C. or more; and
unloading the one of the substrate from the substrate standby portion and inserting the substrate into the cassette after the temperature of the substrate is reduced to less than 100° C.

9. The vapor phase growth method according to claim wherein the cassette is made of a resin.

10. The vapor phase growth method according to claim 8,
wherein the substrate standby portion is made of quartz glass, ceramics, or metal.
